(19) United States
(12) Patent Application Publication
(10) Pub. No.: US 2001/0005325 A1
(43) Pub. Date: Jun. 28, 2001

(54) Semiconductor memory device

(75) Inventors: Makoto Kitayama, Tokyo (JP); Yukio Fukuzo, Tokyo (JP); Takashi Obara, Tokyo (JP); Yasuji Koshikawa, Tokyo (JP); Toru Chonan, Tokyo (JP); Yasushi Matsubara, Tokyo (JP); Hideki Mitou, Tokyo (JP)

Correspondence Address: OSTROLENK FABER GERB & SOFFEN, 1180 AVENUE OF THE AMERICAS, NEW YORK, NY, 100368403

(73) Assignee: NEC Corporation

(21) Appl. No.: 09/734,815

(22) Filed: Dec. 12, 2000

(30) Foreign Application Priority Data
Dec. 13, 1999 (JP) 11-353504

(51) Int. Cl. G11C 5/06

(52) U.S. Cl. 365/63

(57) ABSTRACT

A semiconductor memory device according to the invention comprises a first memory cell region, a second memory cell region, and a sense-amplifier row region disposed between the first and second memory cell regions, wherein the sense-amplifier row region has therein a plurality of transistor rows constituting a plurality of sense-amplifiers, at least one power-supply side sense-amplifier driver transistor disposed on the side f the first memory cell region of the plurality of transistor rows, and at least one ground side sense-amplifier driver transistor disposed on the side of the second memory cell region of the plurality of transistor rows.

### BACKGROUND OF THE INVENTION

1. Field of the Invention

The present invention relates to a semiconductor memory device, and more particularly, it relates to a semiconductor memory device that comprises a sense-amplifier row having a plurality of sense-amplifiers arrayed therein and sense-amplifier drivers for controlling each of the sense-amplifiers.

2. Description of the Related Art

One known type of the prior art semiconductor devices is disclosed in Japanese Patent Publication No. Hei 6-162779.

This disclosed semiconductor memory device has such a configuration shown in FIG. 5 that memory cell regions 120 and 130 are arranged as sandwiching the sense-amplifier row 110 and, on opposite lateral sides of these memory cell regions 120 and 130, sub-word drivers 140 and 150 are formed as laid across the sense-amplifier row 110 respectively.

Cross regions 160 and 170 where the sense-amplifier row 110 and the sub-word drivers 140 and 150 are respectively superposed one on the other are formed as a power-supply-side sense-amplifier driver (SAP driver) 160a and a ground-side sense-amplifier driver (SAN driver) 170a respectively.

Furthermore, as shown in FIG. 6, the sense-amplifier driver is comprised of one transistor (hereinafter called a sense-amplifier driver transistor) 160a. This sense-amplifier driver transistor 160a controls connection between a power-supply line 160a2 and a power-supply-side sense-amplifier drive line (SAP drive line) 160a1, while a ground-side sense-amplifier driver transistor 170a controls connection between a ground line 170a2 and a ground-side sense-amplifier drive line (SAN drive line) 170a1.

Therefore, when these two sense-amplifier driver transistors are turned ON, a supply voltage is applied on each of the transistors which constitute the plurality of sense-amplifiers arranged between the SAP drive line 160a1 and the SAN drive line 170a1, thus permitting the sense-amplifiers to be operative.

The above-mentioned prior-art semiconductor memory device has the following problems.

Since the sense-amplifier driver transistors 160a and 170a are respectively arranged in the cross regions 160 and 170 given by array division based on a multi-layered word-line mechanism, the places where the sense-amplifier driver transistors 160a and 170a are arranged, the size of these transistors, and the places where the power-supply line 160a2 and the ground line 170a2 are provided respectively are restricted and so if, resultantly, the resistance values of the sense-amplifier drive lines 160a1 and 170a1 as well as the power-supply line 160a2 and the ground line 170a2 become large, the sense speed is deteriorated.

In order to reduce the resistance values of the sense-amplifier drive lines 160a1 and 170a1, if their wiring liens are widened or the memory cells are divided into a larger number of arrays so that the number of sense-amplifiers to be driven by each of the sense-amplifiers may be reduced, the chip area is increased.

Furthermore, in the case where the power-supply line 160a and the ground line 170a in the regions of the sense-amplifier driver transistors 160a and 170a are supplied from above the sub-word drivers, if the wiring lines of the power-supply line 160a2 and the ground line 170a2 are widened, the sub-word driver region is increased in width, thus increasing the chip size.

Moreover, the sense-amplifier driver transistors 160a and 170a are arranged as dispersed from the sense-amplifier row 110 but as concentrated to each of the sense-amplifiers, to concentrate a charge/discharge current during sense operations to each of the sense-amplifier drive lines 160a1 and 170a1, thus giving rise to a voltage drop due to the wiring resistance.

Therefore, as the source potential of each sense-amplifier changes, i.e. the potential of the P-channel source is lowered, the potential of the N-channel source rises, to deteriorate the drive capacity of each sense-amplifier, thus reducing the sense speed.

Further, since the power-supply line 160a2 and the ground line 170a for the sense-amplifier driver transistors 160a and 170a can also be supplied only from the places where the sense-amplifier driver transistors 160a and 170a, a charge/discharge current during sense operations is concentrated to these power-supply line 160a2 and the ground line 170a2 for the sense-amplifier driver transistors 160a and 170a, to give rise to a voltage drop due to the wiring resistance, which is a factor of deteriorating the sense speed.

### BRIEF SUMMARY OF THE INVENTION

Object of the Invention

It is an object of the present invention to provide a semiconductor memory device capable of improving the sense speed without increasing the chip size.

Summary of the Invention

A semiconductor memory device of the present invention comprises a first memory cell region, a second memory cell region, and a sense-amplifier row region disposed between the first and second memory regions wherein the sense-amplifier row region includes a plurality of transistor rows constituting a plurality of sense amplifiers, at least one power-supply side sense-amplifier driver transistor disposed on the side of the first memory cell region of the plurality of transistor rows, and at least one ground side sense-amplifier driver transistor disposed on the side of the second memory cell region of the plurality of transistor rows.

### BRIEF DESCRIPTION OF THE DRAWINGS

The above-mentioned and other objects, features, and advantages of this invention will become more apparent by reference to the following detailed description of the invention taken in conjunction with the accompanying drawings, wherein:

FIG. 1 is a layout showing a rough configuration of a semiconductor memory device of the present embodiment;

FIG. 2 is a plan view showing a configuration of a sense-amplifier row;

FIG. 3 is a plan view showing a state where the sense-amplifier row is divided into a plurality of gates;

FIG. 4 is a plan view showing a state where a proportion between the power-supply side and the ground side is changed for the sense-amplifier driver;

FIG. 5 is a layout showing a rough configuration of a prior art semiconductor memory device; and

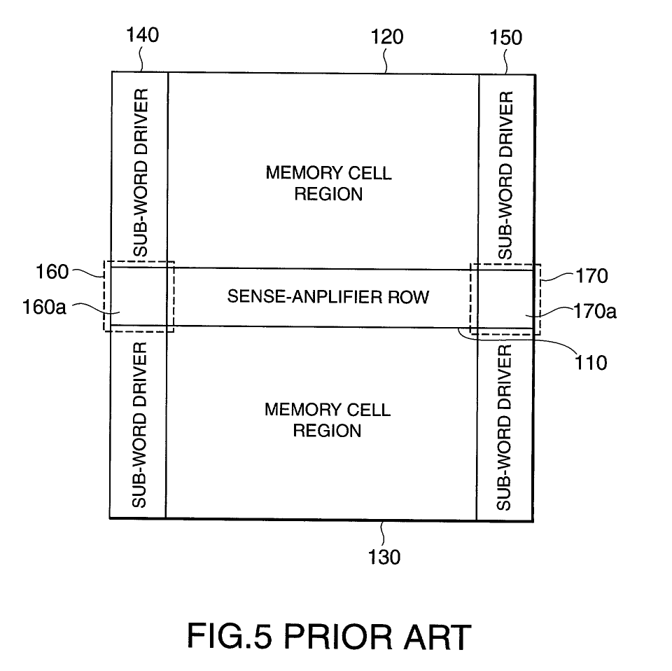

FIG. 6 is a plan view showing a configuration of a prior art sense-amplifier row.

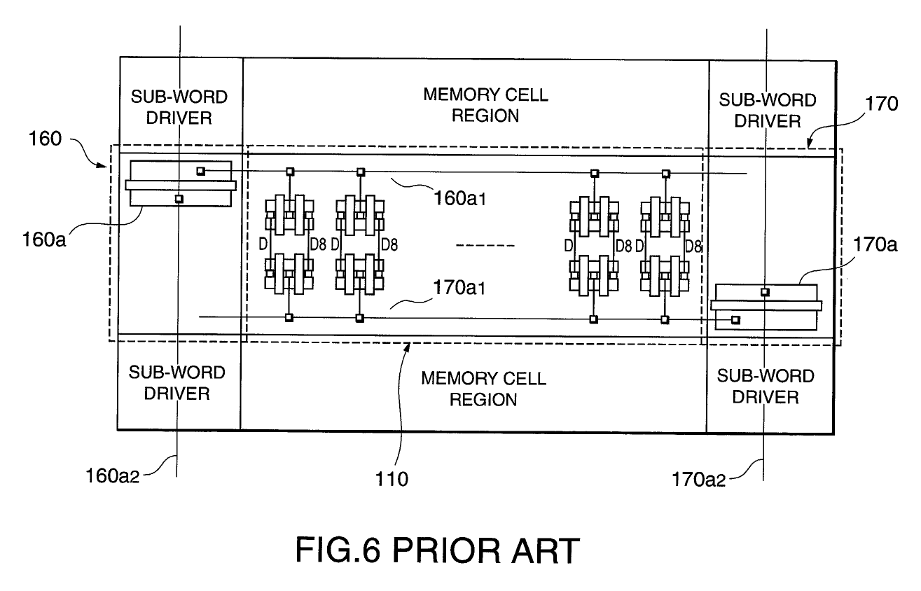

### DESCRIPTION OF THE PREFERRED EMBODIMENTS

The following will describe some embodiments of the present invention with reference to the attached drawings.

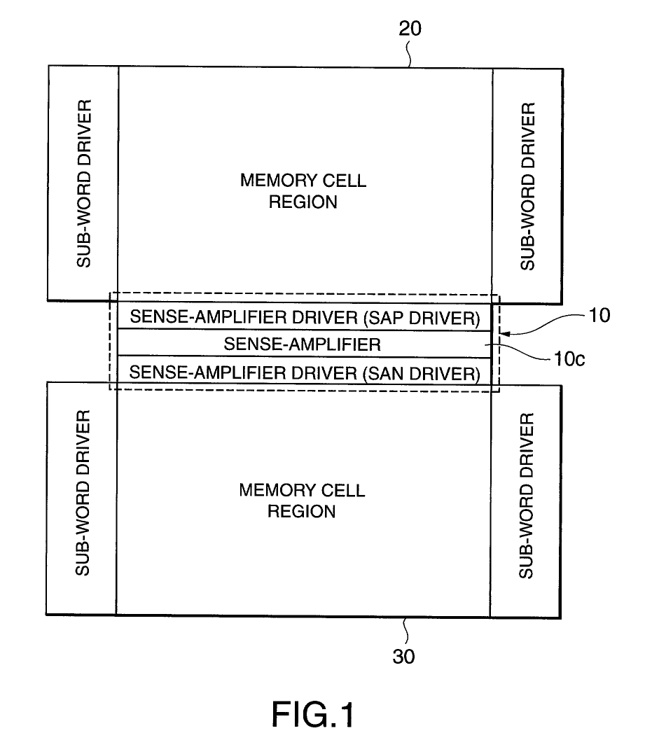

In a semiconductor memory device of the invention, as shown in FIG. 1, a pair of memory cell regions 20 and 30 are disposed with a sense-amplifier row 10 sandwiched therebetween and, on the opposite sides of these memory cell regions are disposed respective sub-word drivers.

The sense-amplifier row 10 comprises a power-supply side sense-amplifier driver (SAP driver) adjacent the memory cell region 20, a ground side sense-amplifier driver (SAN driver) adjacent the memory cell region 30, and a plurality of sense-amplifiers 10c disposed between the power-supply side sense-amplifier driver and the ground side sense-amplifier driver.

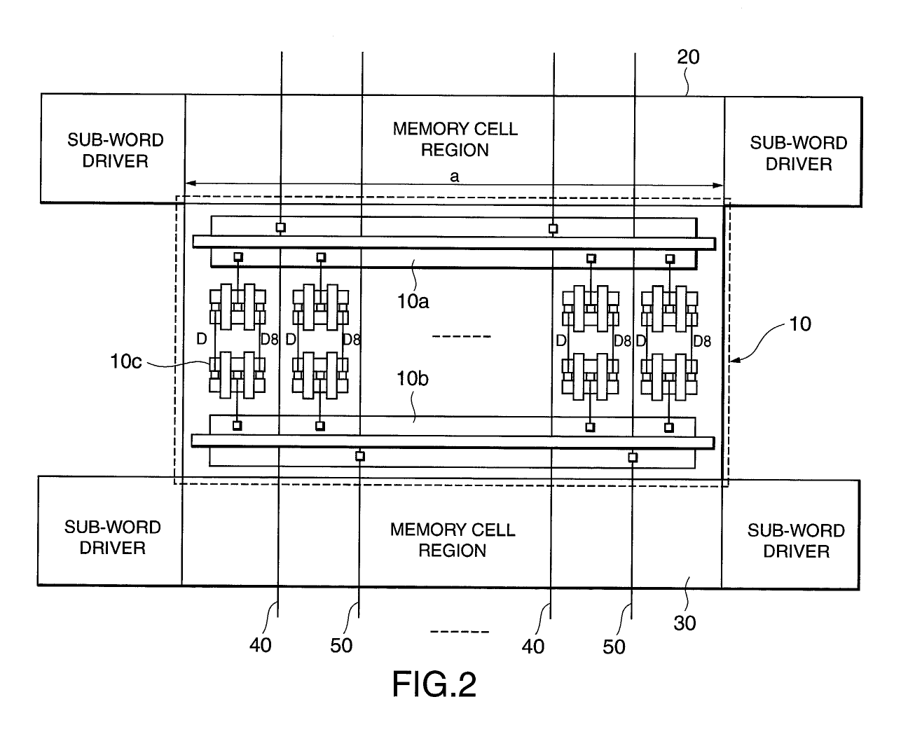

These sense-amplifier drivers shown in FIG. 1 are each comprised of one power-supply side sense-amplifier driver transistor 10a and a ground side sense-amplifier driver transistor 10b. The two driver transistors 10a and 10b are formed, as show in FIG. 2, in their respective regions approximately parallel to the opposing surfaces of the memory cell regions 20 and 30.

The power-supply side sense-amplifier driver transistor 10a and the ground side sense-amplifier driver transistor 10b are connected to a power-supply terminal and a ground terminal of each of the sense-amplifiers 10c respectively, thus supplying a voltage for driving the sense-amplifiers.

It is to be noted that the memory cell regions 20 and 30 are disposed with a predetermined spacing therebetween, while the sense-amplifier row 10 disposed between these memory cell regions 20 and 30 is formed so as to have a substantially uniform width.

Therefore, the width of the sense-amplifier row 10 becomes the gate width of the power-supply side sense-amplifier driver transistor 10a and the ground side sense-amplifier driver transistor 10b. Moreover, the source region and the drain region of the transistors 10a and 10b are formed along respective sides of the memory cell regions 20 and 30 in parallel with word lines (not shown) formed in the memory cell regions.

The outputs (drains) of the power-supply side sense-amplifier driver transistor 10a and the ground side sense-amplifier driver transistor 10b and the sources of the sense-amplifiers 10c of the sense-amplifier row 10 are disposed close to each other and directly interconnected.

With this configuration, therefore, the power-supply side sense-amplifier drive line and ground side sense-amplifier drive line can be eliminated in layout which have conventionally been disposed between the power-supply side sense-amplifier driver transistor 10a and the ground side sense-amplifier driver transistor 10b, thus avoiding a drive voltage drop due to electrical resistance produced at the power-supply side sense-amplifier drive line and the ground side sense-amplifier drive line.

Furthermore, at the places where the prior art power-supply side sense-amplifier drive line and the ground side sense-amplifier drive line have been disposed, the power-supply side sense-amplifier driver transistor 10a and the ground side sense-amplifier driver transistor 10b can be disposed respectively, thus not hampering reduction in the chip size in processes.

Moreover, a plurality of power-supply lines 40 and a plurality of ground lines 50 for the power-supply side sense-amplifier driver transistor 10a and the ground side sense-amplifier driver transistor 10b are disposed in parallel with each other within the width of the memory cell regions 20 and 30 and respectively connected to the power-supply side sense-amplifier driver transistor 10a and the ground side sense-amplifier driver transistor 10b, thus lowering the resistance of the power-supply line 40 and the ground line 50 for the power-supply side sense-amplifier driver transistor 10a and the ground side sense-amplifier driver transistor 10b.

Since the power-supply line 40 and the ground line 50 are disposed within the width occupied by the memory cell regions 20 and 30, they do not affect the chip size, to enable providing a sufficient effective conducting width of the power-supply line 40 and the ground line 50, thus suppressing a voltage drop due to their resistance.

It is to be noted that since the power-supply line 40 and the ground line 50 pass through a dead space between the YSWs (bit line ENABLE signal lines), they do not contribute to an increase in the chip area, so that by disposing the sense-amplifier drivers 10a and 10b as thin as possible in the sense-amplifier row 10, an increase in the area of the chip can be suppressed in which the sense-amplifier drivers 10a and 10b are disposed, because the sense-amplifier row 10 is sufficiently small as compared to the memory cell regions 20 and 30.

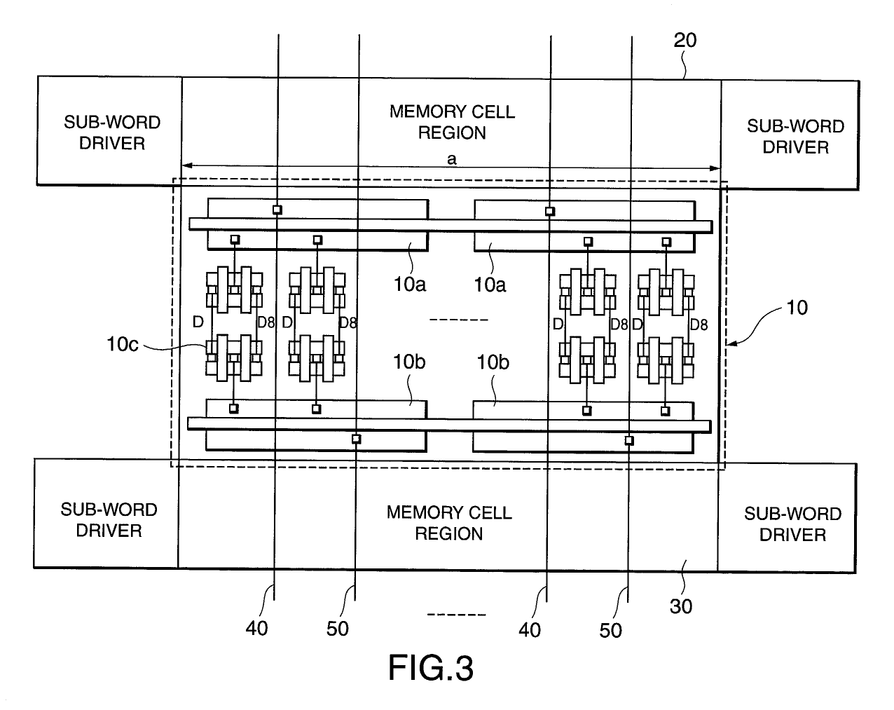

In this embodiment, the sense-amplifier driver transistors 10a and 10b are each comprised of one gate, but this configuration is one of the possible examples, and in fact, as shown in FIG. 3, these transistors can each be divided into a plurality of gates in the sense-amplifier row 10, in the case of which also almost the same effects can be obtained.

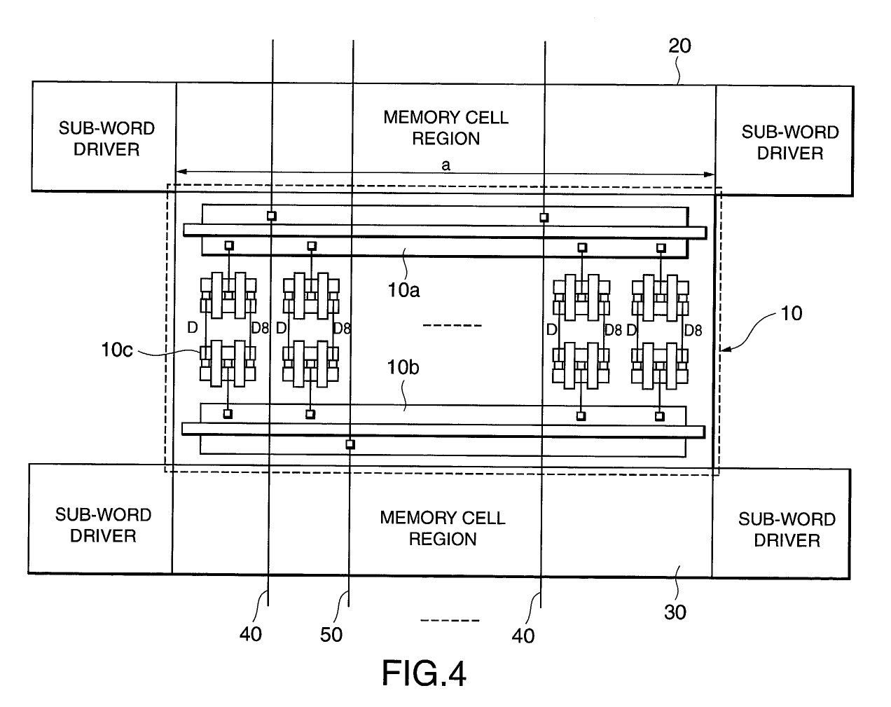

Furthermore, the number of the power-supply lines 40 and that of the ground lines 50 for the sense-amplifier driver transistors 10a and 10b passing between the YSWs must not necessarily be the same as each other but, as shown in FIG. 4, their proportion in number may be changed for optimization according to the capacities of the sense-amplifiers 10c, the power supply, and the ground.

The following will describe the operations of the semiconductor memory device of the present embodiment.

Since there are no sense-amplifier drive lines provided in this embodiment, the power-supply side sense-amplifier driver transistor 10a and the ground side sense-amplifier driver transistor 10b can be connected with the sense-amplifiers 10c with a low resistance, thus reducing the resistance of a node common to the sense-amplifiers.

This configuration is equivalent to such a configuration that the power-supply side sense-amplifier drive line and the ground side sense-amplifier drive line are eliminated and the sense-amplifiers 10c of the sense-amplifier row 10 are disposed as dispersed against the sense-amplifier driver transistors 10a and 10b, thus sufficiently dispersing the charge/discharge current during sensing.

Furthermore, the power-supply line 40 and the ground line 50 are increased in width for the power-supply side sense-amplifier driver transistor 10a and the ground side sense-amplifier driver transistor 10b, to reduce the resistance of these power-supply line 40 and the ground line 50 of the power-supply side sense-amplifier driver transistor 10a and the ground side sense-amplifier driver transistor 10b.

Since the power-supply lines 40 and the ground line 50 are provided more than one each for the power-supply side sense-amplifier driver transistor 10a and the ground side sense-amplifier driver transistor 10b, the concentration of the charge/discharge current during sensing can be avoided.

Therefore, a sense-amplifier drive voltage with a small fluctuation can be supplied to the sense-amplifiers 10c, to suppress a drop in the sense-amplifier drive voltage, thus improving the sense speed.

Thus, the power-supply side sense-amplifier driver transistor 10a and the ground side sense-amplifier driver transistor 10b disposed in the sense-amplifier row 10 are respectively connected to the sense-amplifier 10c and so supplied with a sense-amplifier drive voltage, to suppress an increase in the chip size, thereby improving the sense speed.

As described above, the invention can provide a semiconductor memory device capable of improving the sense speed without increasing the chip size.

Although the invention has been described with reference to specific embodiments, this description is not meant to be construed in a limiting sense. Various modifications of the disclosed embodiments will become apparent to persons in the art upon reference to the description of the invention. It is therefore contemplated that the appended claims will cover any modifications or embodiments as fall within the true scope of the invention.

What is claimed is:

1. A semiconductor memory device comprising:
a first memory cell region;
a second memory cell region; and
a sense-amplifier row region disposed between said first memory cell region and said second memory cell region,
wherein said sense-amplifier row region has therein a plurality of transistor rows constituting a plurality of sense-amplifiers, at least one power-supply side sense-amplifier driver transistor disposed on a side of said first memory cell region of said plurality of transistor rows, and at least one ground side sense-amplifier driver transistor disposed on a side of said second memory cell region of said plurality of transistor rows.

2. The semiconductor memory device according to claim 1, wherein said power-supply side sense-amplifier driver transistor connect a power-supply terminal of said plurality of sense-amplifier and a power-supply line with each other, while said ground side sense-amplifier driver transistor connects a ground terminal of said plurality of sense-amplifier and a ground line with each other.

3. The semiconductor memory device according to claim 2, wherein each of said power-supply line and said ground line consists of a plurality of lines.

4. The semiconductor memory device according to claim 3, wherein said power-supply line and said ground line consists of different numbers of lines.

5. The semiconductor memory device according to any one of said preceding Claims, wherein a source region and a drain region of said power-supply side sense-amplifier driver transistor are formed along a side of said first memory cell region in parallel with a word line formed in said first memory cell region, while a source region and a drain region of said ground side sense-amplifier driver transistor are formed along a side of said second memory cell region in parallel with a word line formed in said second memory cell region.

6. The semiconductor memory device according to claim 1, wherein said power-supply side sense-amplifier driver transistor and said ground side sense-amplifier driver transistor each consist of a plurality of transistors.
